(19) United States
(12) Patent Application Publication
(10) Pub. No.: US 2008/0185597 A1
(43) Pub. Date: Aug. 7, 2008

(54) LIGHT-EMITTING MODULE

(75) Inventor: Ming-Che WU, Chia-Yi City (TW)

Correspondence Address: FOLEY AND LARDNER LLP;SUITE 500, 3000 K STREET NW, WASHINGTON, DC, 20007, US

(73) Assignee: UNIVERSAL SCIENTIFIC INDUSTRIAL CO., LTD.

(21) Appl. No.: 11/671,566

(22) Filed: Feb. 6, 2007

(51) Int. Cl. H01L 33/00

(52) U.S. Cl. 257/88; 257/99; 257/E33.001

(57) ABSTRACT

A light-emitting module includes a base, a connecting unit disposed on the base, a light-emitting unit disposed on the base, and a drive unit electrically coupled to and bridging the connecting unit and the light-emitting unit for driving the light-emitting unit. The base includes a plurality of first bonding pads formed thereon. The connecting unit is electrically coupled to the first bonding pads, and the light-emitting unit is electrically coupled to the first bonding pads via the drive unit and the connecting unit. The connecting unit includes a plurality of connectors aligned in a first direction of the base, and the light-emitting unit includes a plurality of light-emitting elements aligned in the first direction and respectively spaced apart from and aligned with the connectors in a second direction perpendicular to the first direction.

### CROSS-REFERENCE TO RELATED APPLICATION

This application claims priority of Taiwanese Application No. 095219556, filed on Nov. 6, 2006.

### BACKGROUND OF THE INVENTION

1. Field of the Invention

The present invention relates to a light-emitting module, more particularly to a light-emitting module utilizing a configuration that allows for a compact overall structure.

2. Description of the Related Art

Referring to FIG. 1, a conventional light-emitting module 1 includes a base 11, a plurality of drive chips 12, a plurality of light-emitting elements 13, and a plurality of gold wires 14,15. A plurality of bonding pads 111 are formed on the base 11. The drive chips 12 are disposed on the base 11 and aligned in a first direction (X), and the light-emitting elements 13 are also disposed on the base 11 and aligned in the first direction (X). The light-emitting elements 13 are respectively spaced apart from and aligned with the drive chips 12 in a second direction (Y) that is perpendicular to the first direction (X). The gold wires 14 electrically and respectively couple the bonding pads 111 of the base 11 to a corresponding one of the drive chips 12, and the gold wires 15 electrically couple the light-emitting elements 13 to a corresponding one of the drive chips 12. A wire bonding technique is used for the connection the gold wires 14, 15 described above. Through such interconnections, the light-emitting elements 13 are electrically coupled to the bonding pads 111 of the base 11 through the drive chips 12.

In the above configuration, a significant number of wire bonds is required with respect to the gold wires 14, and an even larger number of wire bonds is required with respect to the gold wires 15 (e.g., approximately ten times the number required for the gold wires 14). This places a significant burden on the manufacturing process. That is, the large number of wire bonds makes the manufacturing process extremely time-consuming, complicated, and costly.

Referring to FIG. 2, another conventional light-emitting module 2 is disclosed that at least partially overcomes the above drawback. The light-emitting module 2 includes a base 21 having a plurality of bonding pads 211 formed thereon, a plurality of drive chips 22, a plurality of light-emitting elements 23, a plurality of gold wires 24, and a plurality of connectors 25. Except for the use of the connectors 25 to interconnect the drive chips 22 and the light-emitting elements 23, all other aspects of this conventional light-emitting module 2 are substantially identical to those described above with respect to the light-emitting module 1 of FIG. 1.

The connectors 25 are electrically and respectively coupled to corresponding pairs of the drive chips 22 and the light-emitting elements 23 utilizing flip chip mounting technology and by bridging the pairs of the drive chips 22 and the light-emitting elements 23. Through this structure, the number of wire bonds is significantly decreased when compared to the previously described light-emitting module 1 of FIG. 1.

However, the light-emitting module 2 of this conventional configuration is not without drawbacks. Namely, since there is a height difference between the drive chips 22 and the light-emitting elements 23, the connectors 25 are provided at an angle when bridging these two elements. In order to prevent the angle of the connectors 25 from being too large and thereby making ineffective the electrical connections, a suitable spacing is provided between the pairs of the drive chips 22 and the light-emitting elements 23, and a width of each of the connectors 25 along the second direction (Y) is increased so that the connectors 25 may perform their bridging function. Hence, the connectors 25 must be formed to a substantial width, and any reduction in the width thereof is not possible. This coupled with the fact that the drive chips 22 inherently have a large width in the second direction (Y) to allow for sufficient space for the circuitry provided thereon, the light-emitting module 2 has a relatively large overall width in the second direction (Y). This places undesired design restrictions on the light-emitting module 2 and increases manufacturing costs due to the large amount of materials required.

### SUMMARY OF THE INVENTION

Therefore, the object of this invention is to provide a light-emitting module that allows for a compact overall structure.

The light-emitting module of this invention comprises a base, a connecting unit disposed on the base, a light-emitting unit disposed on the base, and a drive unit electrically coupled to and bridging the connecting unit and the light-emitting unit for driving the light-emitting unit.

The base includes a plurality of first bonding pads formed thereon. The connecting unit is electrically coupled to the first bonding pads, and the light-emitting unit is electrically coupled to the first bonding pads via the drive unit and the connecting unit.

The connecting unit includes a plurality of connectors aligned in a first direction of the base, and the light-emitting unit includes a plurality of light-emitting elements aligned in the first direction and respectively spaced apart from and aligned with the connectors in a second direction perpendicular to the first direction.

### BRIEF DESCRIPTION OF THE DRAWINGS

Other features and advantages of the present invention will become apparent in the following detailed description of the preferred embodiment with reference to the accompanying drawings, of which:

FIG. 1 a fragmentary perspective view of a conventional light-emitting module;

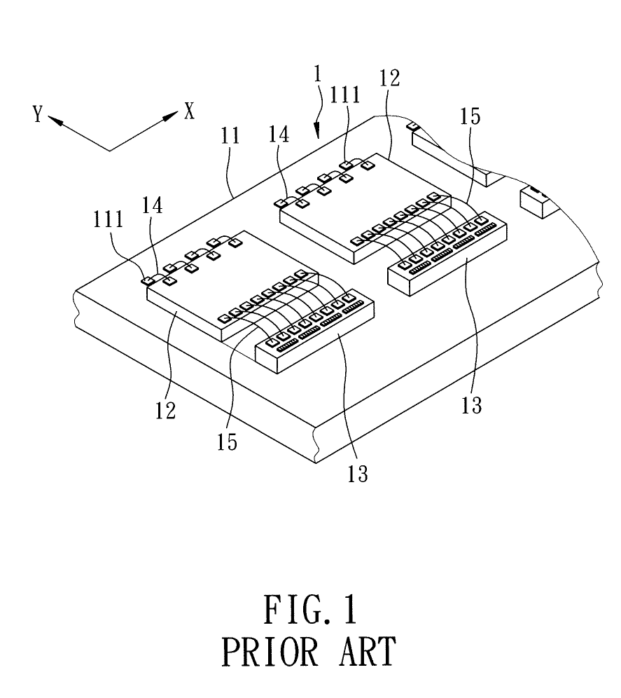

FIG. 2 is a fragmentary side view of another conventional light-emitting module;

FIG. 3 a fragmentary perspective view of a light-emitting module according to a preferred embodiment of the present invention;

FIG. 4 is a fragmentary side view of the preferred embodiment; and

FIG. 5A is a fragmentary schematic top view of the conventional light-emitting module of FIG. 2; and

FIG. 5B is a fragmentary schematic top view of the preferred embodiment.

### DETAILED DESCRIPTION OF THE PREFERRED EMBODIMENT

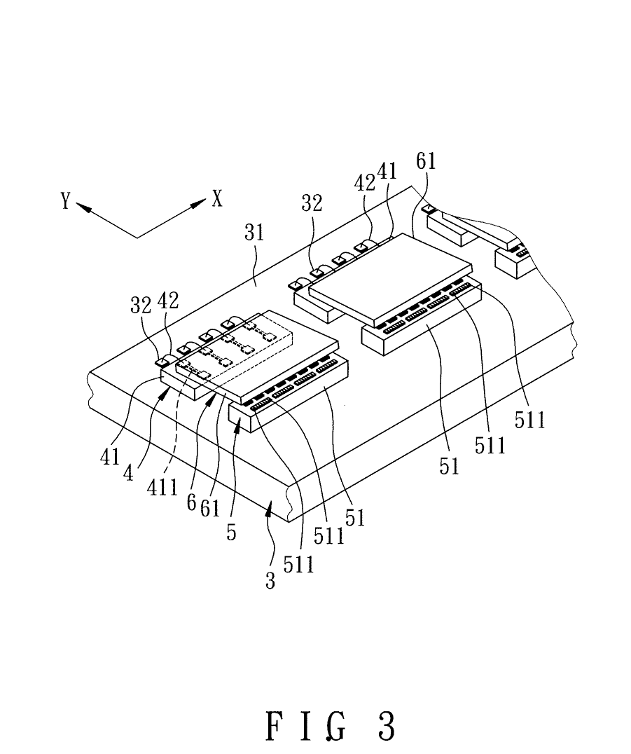

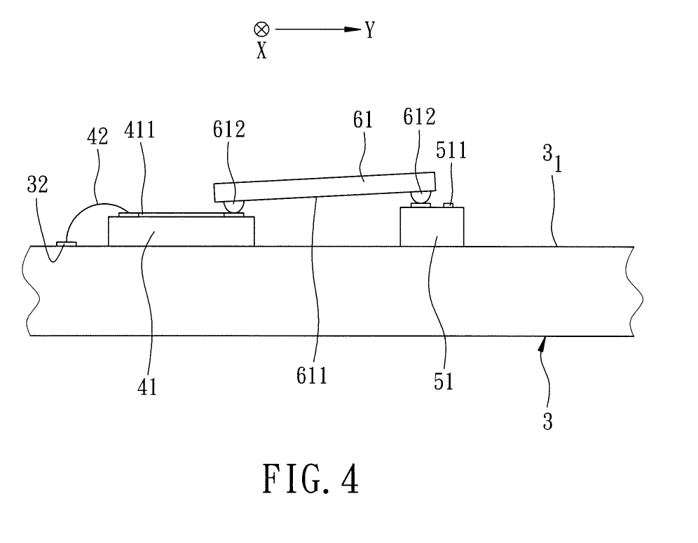

Referring to FIGS. 3, 4, and 5B, a light-emitting module according to a preferred embodiment of the present invention includes a base 3, a connecting unit 4, a light-emitting unit 5, and a drive unit 6.

The base 3 has a substantially planar upper surface 31, and includes a plurality of first bonding pads 32 formed on the upper surface 31 and aligned in a first direction (X). The base 3 is in the form of a printed circuit board in this embodiment.

The connecting unit 4 includes a plurality of connectors 41 adhered to the upper surface 31 of the base 3 and aligned in the first direction (X), and a plurality of connecting wires 42. Each of the connectors 41 includes a plurality of conducting lines 411 formed thereon at locations corresponding respectively to corresponding ones of the first bonding pads 32. For each of the connectors 41, the connecting wires 42 electrically and respectively couple the conducting lines 411 to the corresponding ones of the first bonding pads 32 of the base 3. A wire bonding technique is used to connect the connecting wires 42 to the first bonding pads 32.

The light-emitting unit 5 includes a plurality of light-emitting elements 51 mounted on the upper surface 31 of the base 3 and aligned in the first direction (X). The light-emitting elements 51 are respectively spaced apart from and aligned with the connectors 41 in a second direction (Y) that is perpendicular to the first direction (X). Each of the light-emitting elements 51 includes a plurality of light-emitting diode (LED) chips 511. Each of the LED chips 511 may be independently driven to generate light.

The drive unit 6 is electrically coupled to and bridges the connecting unit 4 and the light-emitting unit 5 for driving the light-emitting unit 5. The drive unit 6 includes a plurality of drive elements 61 aligned in the first direction (X). The drive elements 61 are drive circuit chips in this embodiment.

Each of the drive elements 61 includes a flip chip surface 611 facing the connectors 41 and the light-emitting elements 51, and two rows of second bonding pads 612 formed on the flip chip surface 611 on opposite sides of the drive element 61. Each of the rows of the second bonding pads 612 is aligned in the first direction (X). That is, the flip chip surface 611 of each of the drive elements 61 has edge portions extending in the first direction (X) and opposite one another in the second direction (Y), and the two rows of the second bonding pads 612 are respectively disposed on the edge portions. Each of the drive elements 61 bridges a corresponding pair of one of the connectors 41 and one of the light-emitting elements 51, and is electrically coupled to the connector 41 and the light-emitting element 51 respectively through the two rows of the second bonding pads 612 and by use of flip chip mounting technology.

For each of the drive elements 61, the second bonding pads 612 of one of the rows of the same are electrically coupled to the corresponding ones of the first bonding pads 32 respectively through the conducting lines 411 of the corresponding connector 41 and through corresponding ones of the connecting wires 42. In addition, the second bonding pads 612 of the other row are electrically coupled to selected ones of the light-emitting diode chips 511 of the corresponding light-emitting element 51.

Through the interconnections described above, the light-emitting unit 5 is in a state of electrical connection with the drive unit 6, the connecting unit 4, and the first bonding pads 32 of the base 3. Also, each of the light-emitting diode chips 511 is electrically coupled to a respective one of the first bonding pads 32 through the drive unit 6, a respective one of the connecting wires 42, and a respective one of the conducting lines 411.

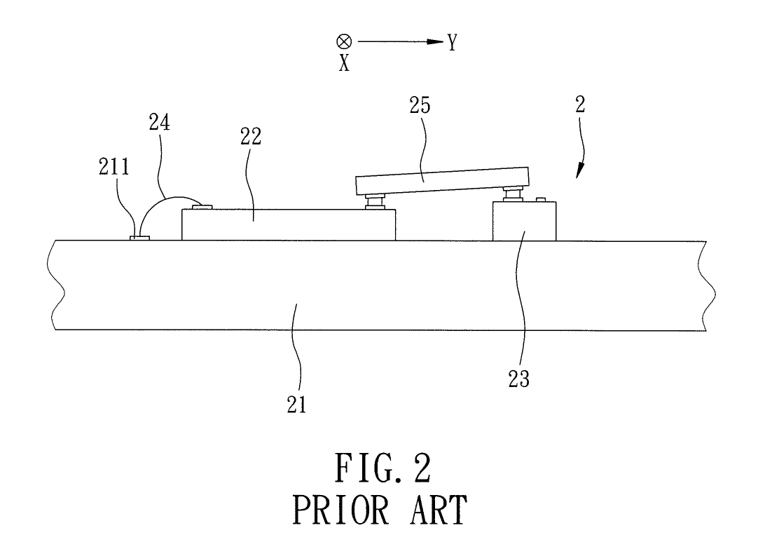

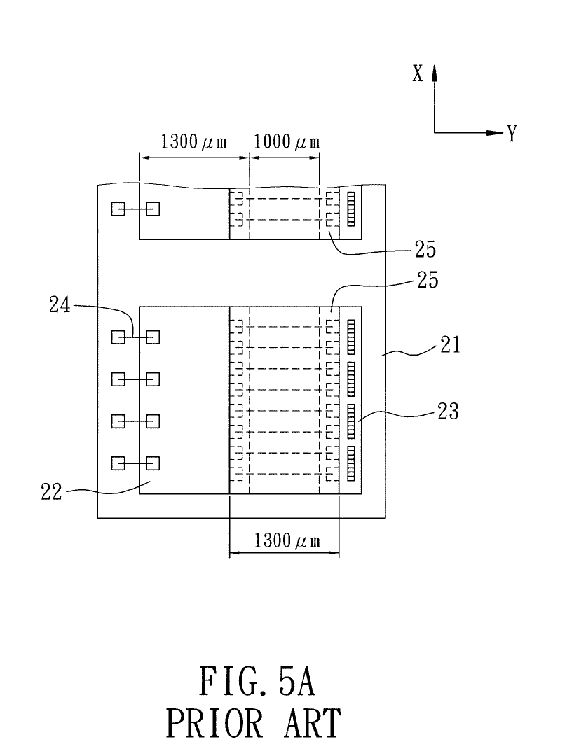

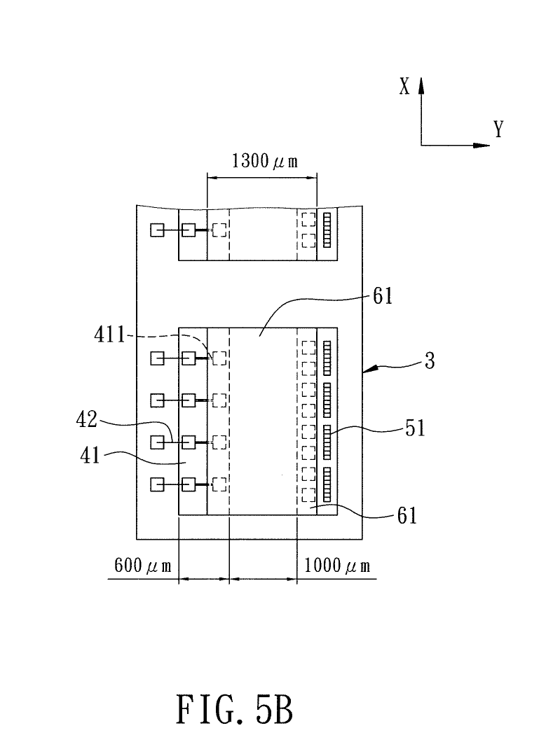

Additional reference is made to FIGS. 5A and 5B. Since the drive elements 61 include a somewhat complicated circuit design that requires a relatively large area, the drive elements 61 are typically larger than the connectors 41. The width of commercially available drive elements is typically between 1000 and 1300 micrometers. It is next assumed that a bridging width (i.e., the spacing between the connecting unit 4 and the light-emitting unit 5 of the present invention, and between corresponding pairs of the drive chips 22 and light-emitting elements 23 of the conventional light-emitting module 2 of FIG. 2) is 1000 micrometers to ensure a minimal slanting angle of the element that performs bridging.

In the case of the light-emitting module 2 of FIG. 2, this fact scenario translates into a width of the connectors 25 of at least 1000 micrometers. On the other hand, in the case of the present invention, the width of the drive elements 61, which perform the bridging function in the present invention, is already at least 1000 micrometers, and therefore do not require any change in design. Since the connectors 41 do not perform a bridging function in the present invention, and function, instead, to provide a sufficient area to allow for the formation of the conducting lines 411, the width of the connectors 41 may be reduced. In particular, the width of the connectors 41 may be decreased to between about 600 and 700 micrometers, which is a reduction of at least 30% over the conventional design of FIG. 2. This allows for the overall width of the light-emitting module of the present invention to be reduced, thereby ultimately resulting in reduced manufacturing costs.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A light-emitting module, comprising:
a base;
a connecting unit disposed on said base;
a light-emitting unit disposed on said base; and
a drive unit electrically coupled to and bridging said connecting unit and said light-emitting unit for driving said light-emitting unit.

2. The light-emitting module of claim 1, wherein said base includes a plurality of first bonding pads formed thereon, said connecting unit being electrically coupled to said first bonding pads, said light-emitting unit being electrically coupled to said first bonding pads via said drive unit and said connecting unit.

3. The light-emitting module of claim 2, wherein said connecting unit includes a plurality of connectors aligned in a first direction of said base, and said light-emitting unit includes a plurality of light-emitting elements aligned in the first direction and respectively spaced apart from and aligned with said connectors in a second direction perpendicular to the first direction.

4. The light-emitting module of claim 3, wherein said connecting unit further includes a plurality of connecting wires, and each of said connectors includes a plurality of conducting lines formed thereon and electrically coupled to said drive unit, said connecting wires electrically and respectively coupling said conducting lines of each of said connectors to corresponding ones of said first bonding pads of said base.

5. The light-emitting module of claim 4, wherein each of said light-emitting elements includes a plurality of light-emitting diode chips, each of which is electrically coupled to a respective one of said first bonding pads through said drive unit, a respective one of said connecting wires, and a respective one of said conducting lines.

6. The light-emitting module of claim 5, wherein said drive unit includes a plurality of drive elements aligned in the first direction, each of said drive elements bridging a corresponding one of said connectors and a corresponding one of said light-emitting elements.

7. The light-emitting module of claim 6, wherein each of said drive elements includes a flip chip surface facing the corresponding one of said connectors and the corresponding one of said light-emitting elements, and two rows of second bonding pads formed on said flip chip surface, one of the rows of said second bonding pads being electrically and respectively coupled to said first bonding pads respectively through said conducting lines and said connecting wires, and the other of the rows of said second bonding pads being electrically coupled to selected ones of said light-emitting diode chips of a respective one of said light-emitting elements.

8. The light-emitting module of claim 7, wherein said flip chip surface has edge portions extending in the first direction and opposite one another in the second direction, one of the rows of said second bonding pads being formed on one of said edge portions, the other of the rows of said second bonding pads being formed on the other of said edge portions.

9. The light-emitting module of claim 1, wherein said base is in the form of a printed circuit board.
